(19) United States
(12) Patent Application Publication
(10) Pub. No.: US 2006/0001062 A1
(43) Pub. Date: Jan. 5, 2006

(54) Method for fabricating CMOS image sensor

(75) Inventor: In Gyun Jeon, Icheon-city (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/175,505

(22) Filed: Jul. 5, 2005

(30) Foreign Application Priority Data
Jul. 5, 2004 (KR) 10-2004-0052007

(51) Int. Cl. H01L 31/062

(52) U.S. Cl. 257/292

(57) ABSTRACT

A method for fabricating a CMOS image sensor is disclosed, to minimize the leakage current and to improve the yield, which includes the steps of preparing a semiconductor substrate including a peripheral circuit and a pixel array, wherein the pixel array is comprised of a photodiode and a readout circuit; defining an active area and a field area in the semiconductor substrate; forming a field oxide layer in the field area of the semiconductor substrate; forming gate electrodes in the peripheral circuit and the readout circuit of the pixel array; forming a photodiode in a photodiode portion of the pixel array; forming source and drain junctions at both sides of the gate electrode in the semiconductor substrate of the active area; forming a salicide prevention layer in the semiconductor substrate of the pixel array; and forming salicide layers in the surface of the gate electrode and the source and drain junctions in the peripheral circuit by using the salicide prevention layer as a mask.

### CROSS-REFERENCE TO RELATED APPLICATIONS

This application claims the benefit of Korean Application No. P2004-52007 filed on Jul. 5, 2004, which is hereby incorporated by reference as if fully set forth herein.

### BACKGROUND OF THE INVENTION

1. Field of the Invention

The present invention relates to a method for fabricating an image sensor, and more particularly, to a method for fabricating a CMOS image sensor to decrease a leakage current.

2. Discussion of the Related Art

Generally, an image sensor is a semiconductor device for converting an optical image into an electric signal. The image sensor can be broadly categorized into a charge coupled device (CCD) and a complementary metal oxide semiconductor (CMOS) image sensor.

In case of the CCD, respective metal-oxide-silicon MOS capacitors are positioned adjacently, wherein electric charge carriers are stored in and transferred to the capacitors. Meanwhile, the CMOS image sensor adopts the CMOS technology of using a control circuit and a signal processing circuit as the peripheral circuit. The CMOS image sensor uses the switching method of sequentially detecting output signals by forming the predetermined number of MOS transistors in correspondence with the number of pixels.

The CCD has the high power consumption and the complicated mask process. Also, it is impossible to provide the signal processing circuit inside the CCD chip, whereby it cannot be formed in one chip. In order to overcome these problems, the sub-micron CMOS fabrication technology has been researched and developed.

The CMOS image sensor may have various types of pixel. Generally, the CMOS image sensor may have a pixel of 3-T (3-Transistor) structure or a pixel of 4-T (4-Transistor) structure. At this time, the pixel of 3-T structure is comprised of one photodiode and three transistors, and the pixel of 4-T structure is comprised of one photodiode and four transistors.

FIG. 1 shows 2×2 pixel array of a 3-T structure CMOS image sensor according to the related art.

In FIG. 1, a unit pixel is comprised of one photodiode PD and a readout circuit. The readout circuit is formed of three transistors. In this case, the three transistors are formed of a reset transistor Rx, a drive transistor Dx and a select transistor Sx. The reset transistor Rx resets optical charges collected in the photodiode PD. Also, the driver transistor Dx functions as a source follow buffer amplifier, and the select transistor Sx is provided for switching and addressing the optical charges.

The plurality of unit pixels, in which each of the unit pixels has the photodiode and the readout circuit, are arranged to form a pixel array. In addition, an addition peripheral circuit is provided to output the optical charged generated in the pixel array.

In the photodiode portion (A) including the photodiode PD, a salicide layer is not formed. However, the salicide layer is formed in the other portions of the readout circuit and the peripheral circuit except the photodiode portion (A).

According as the salicide layer is formed in the readout circuit and the peripheral circuit, it is possible to increase a speed by decreasing a resistance in a signal line and a gate. In the meantime, the salicide layer is not formed in the photodiode portion (A) since the salicide layer reflects the light. In case of the photodiode PD, it is necessary to receive the light and to reproduce the image.

Hereinafter, a method for fabricating a CMOS image sensor according to the related art will be described with reference to the accompanying drawings.

FIG. 2A to FIG. 2H are cross sectional views of the process for fabricating a CMOS image sensor according to the related art, wherein the left side shows a peripheral circuit, and the right side show a pixel array.

First, as shown in FIG. 2A, a semiconductor substrate 10 including a peripheral circuit and a pixel array is defined as an active area and a field area. Then, a trench is formed in the semiconductor substrate 10 of the field area. After that, a field oxide layer 11 of an STI (Shallow Trench Isolation) structure is formed by filling the trench with an insulating layer. Accordingly, the semiconductor substrate 10 is divided into the active area and the field area.

Referring to FIG. 2B, a gate insulating layer and a conductive layer of polysilicon are sequentially deposited on an entire surface of the semiconductor substrate 10. Then, the gate insulating layer and the conductive layer are selectively removed by an etching process of using a mask for patterning gate electrodes. As a result, the gate insulating layer 19 and the gate electrodes 12 are formed in the peripheral circuit and a readout circuit of the pixel array.

Referring to FIG. 2C, impurity ions are implanted to the semiconductor substrate 10 with a mask, thereby forming a photodiode PD. In this case, the mask is provided to define the photodiode PD in the semiconductor substrate 10 of the pixel array. If the semiconductor substrate 10 has the p-type, n-type impurity ions are implanted to the p-type semiconductor substrate so as to form the photodiode PD.

Next, a silicon nitride layer SiN is formed on the entire surface of the semiconductor substrate 10, and is then etch-backed to form insulating layer spacers 13 at both sides of the gate electrode 12.

As shown in FIG. 2D, an insulating layer 14a of oxide type is formed on the entire surface of the semiconductor substrate 10.

As shown in FIG. 2E, a photoresist PR is coated on the insulating layer 14a, and an exposure and development process is performed on the coated photoresist PR, so that the photoresist PR remains on the photodiode PD.

Referring to FIG. 2F, the insulating layer 14a is removed in state of using the remaining photoresist PR as a mask, thereby forming a salicide prevention layer 14. That is, the salicide prevention layer 14 is formed on the photodiode PD.

At this time, the salicide prevention layer 14 and the field oxide layer 11 are formed of the oxide type material. That is, when forming the salicide prevention layer 14, the field oxide layer 11 is damaged, whereby the semiconductor substrate 10 corresponding to the edge of the active area is exposed as shown in “A” of FIG. 2F.

As shown in FIG. 2G, the photoresist PR is removed.

As shown in FIG. 2H, impurity ions are implanted to the semiconductor substrate 10 corresponding to the active area of the peripheral circuit and the readout circuit by using the gate electrode 12 and the insulating spacers 13 as a mask, thereby forming source and drain junctions 15.

After that, salicide layers 16 are formed in the surface of the gate electrode 12 and the source and drain junctions 15 in the readout circuit and the peripheral circuit of the pixel array by performing the salicide process. That is, a refractory metal layer (Co, W, etc.) is deposited on the entire surface of the semiconductor substrate 10 including the salicide prevention layer 14, and then a thermal process is performed on the deposited refractory metal layer. As a result, the deposited refractory metal layer reacts on the silicon of the lower layer, whereby the salicide layer 16 is formed in the interface between the refractory metal layer and the silicon. The semiconductor substrate and the gate electrode are formed of the silicon material. In this respect, the salicide layer 16 is formed on the source and drain junctions 15 and the gate electrode 12. However, the photodiode PD is masked with the salicide prevention layer 14, whereby the salicide layer 16 is not formed in the photodiode PD.

However, the method for fabricating the CMOS image sensor according to the related art has the following disadvantages.

As shown in “B” of FIG. 2H, when forming the salicide prevention layer 14, the field oxide layer 11 is damaged. That is, the salicide layer is formed in the edge of the active area, the interface between the field oxide layer and the active area. In case of the salicide layer formed in the edge of the active area, it may cause the leakage current in the photodiode PD and the source and drain junctions 15 of the pixel array.

The leakage current has the bad influence on the CMOS image sensor. Especially, in case the leakage current increases, the yield is lowered to 0%.

### SUMMARY OF THE INVENTION

Accordingly, the present invention is directed to a method for fabricating a CMOS image sensor that substantially obviates one or more problems due to limitations and disadvantages of the related art.

An object of the present invention is to provide a method for fabricating a CMOS image sensor to minimize the leakage current and to improve the yield.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for fabricating a CMOS image sensor includes the steps of preparing a semiconductor substrate including a peripheral circuit and a pixel array, wherein the pixel array is comprised of a photodiode and a readout circuit; defining an active area and a field area in the semiconductor substrate; forming a field oxide layer in the field area of the semiconductor substrate; forming gate electrodes in the peripheral circuit and the readout circuit of the pixel array; forming a photodiode in a photodiode portion of the pixel array; forming source and drain junctions at both sides of the gate electrode in the semiconductor substrate of the active area; forming a salicide prevention layer in the semiconductor substrate of the pixel array; and forming salicide layers in the surface of the gate electrode and the source and drain junctions in the peripheral circuit by using the salicide prevention layer as a mask.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 shows 2×2 pixel array of a 3-T structure CMOS image sensor according to the related art;

FIG. 2A to FIG. 2H are cross sectional views of the process for fabricating a CMOS image sensor according to the related art; and

FIG. 3A to FIG. 3F are cross sectional views of the process for fabricating a CMOS image sensor according to the present invention.

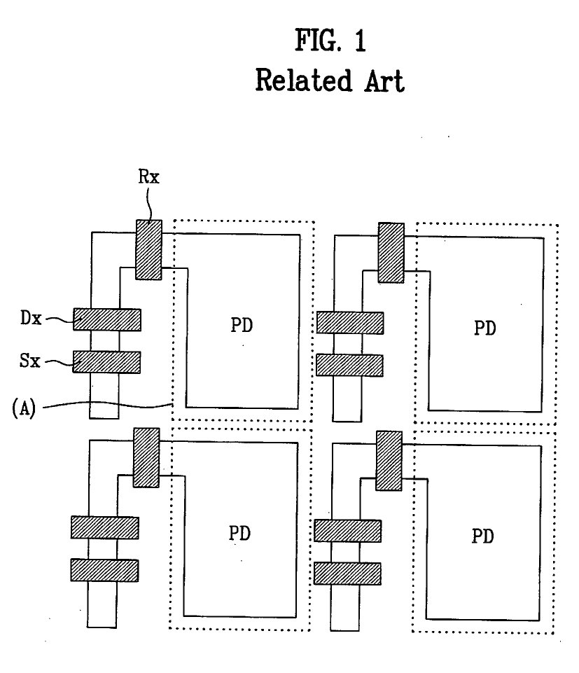

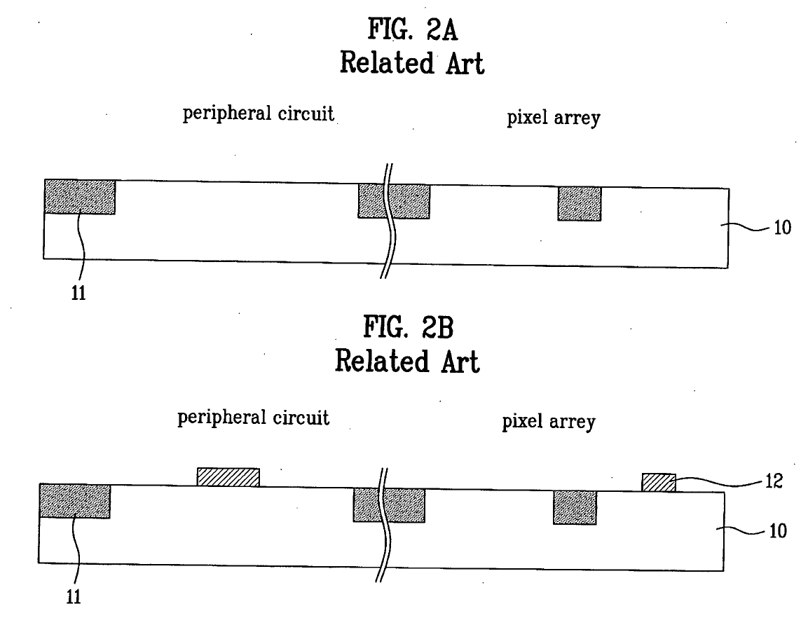

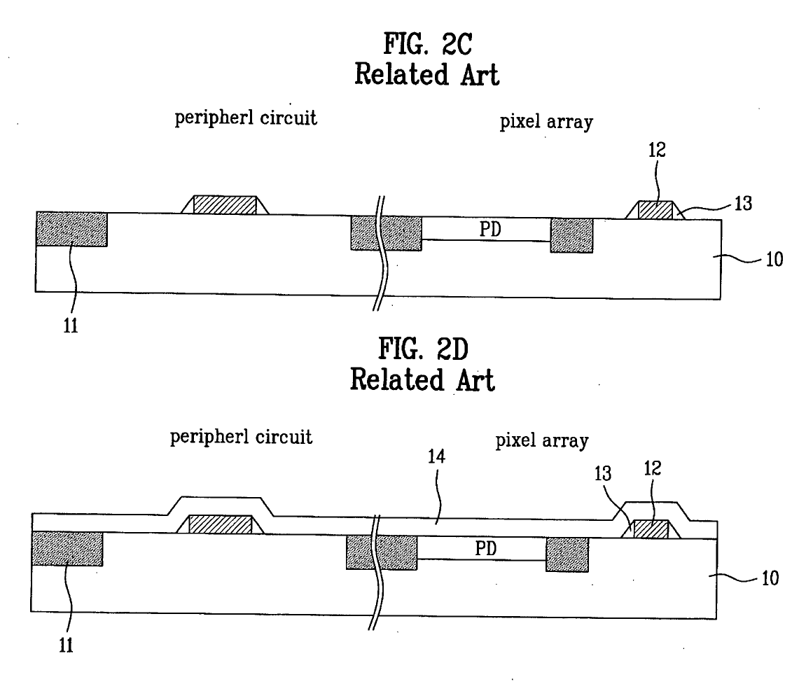

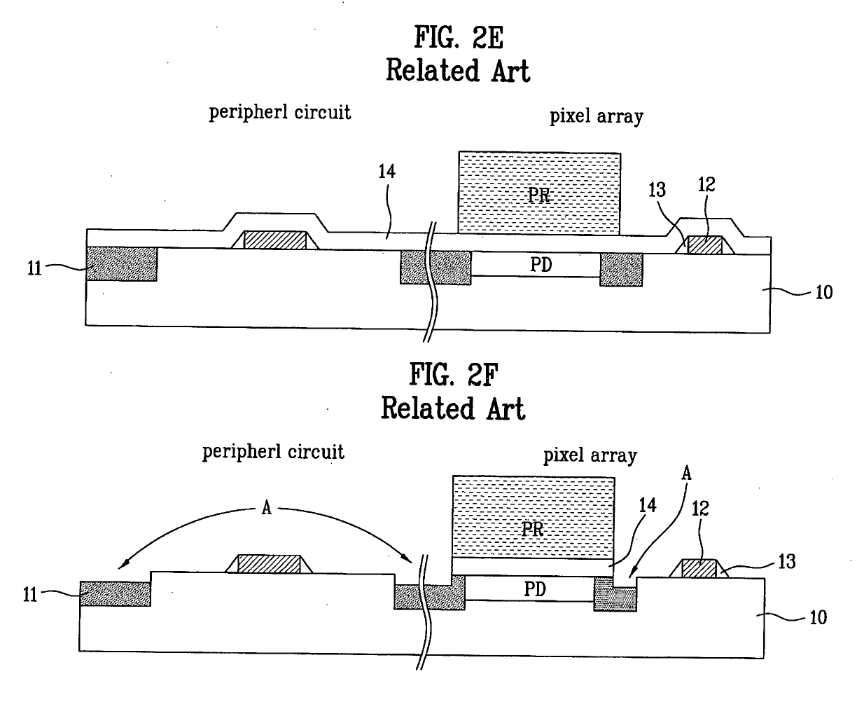

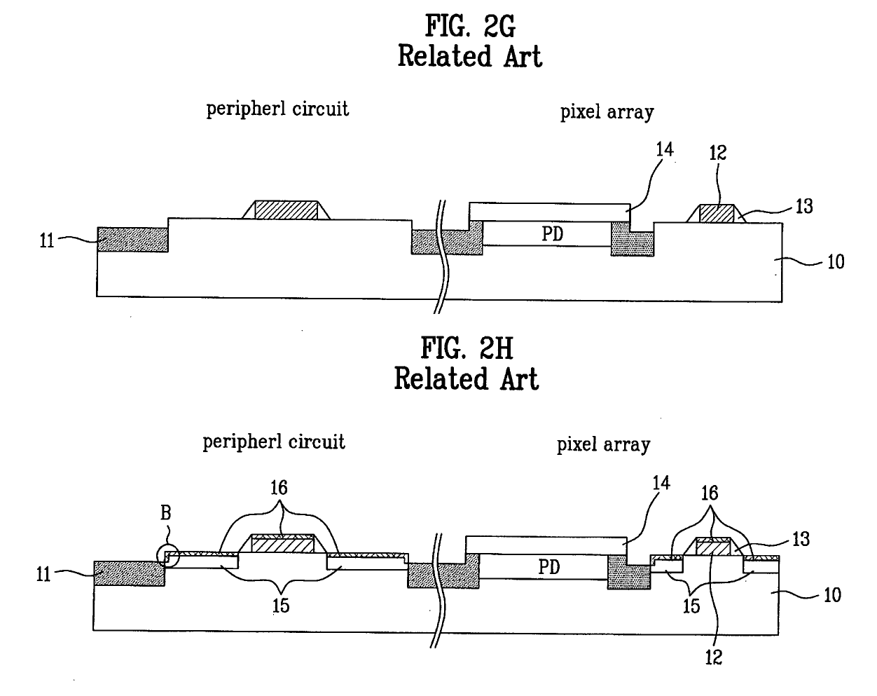

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method for fabricating a CMOS image sensor according to the present invention will be described with reference to the accompanying drawings.

Generally, in a pixel array, a gate electrode requires a low resistance. Accordingly, preferably, a salicide layer is formed in the pixel array. However, the salicide layer may not be formed in source and drain junctions.

In a readout circuit of a pixel array according to the present invention, a salicide layer is formed on a gate electrode, and is not formed in source and drain junctions.

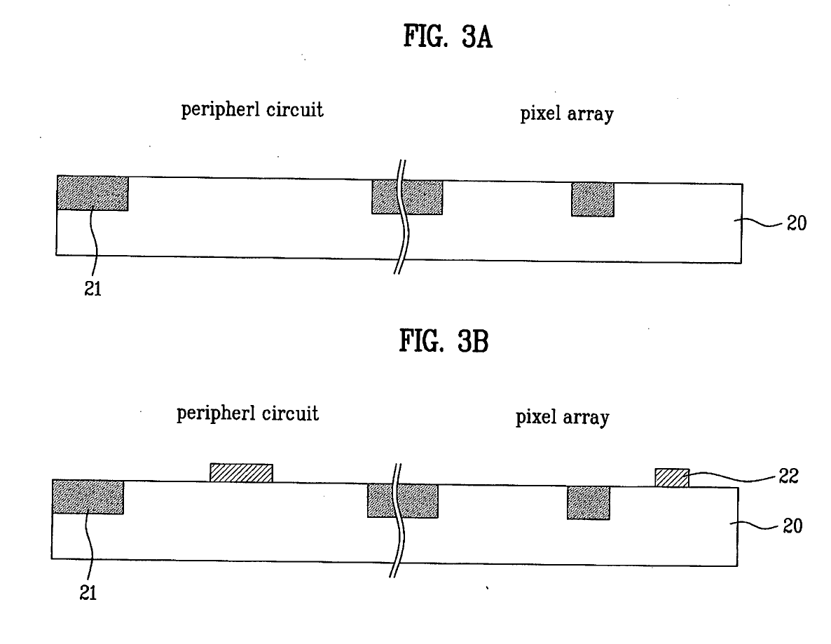

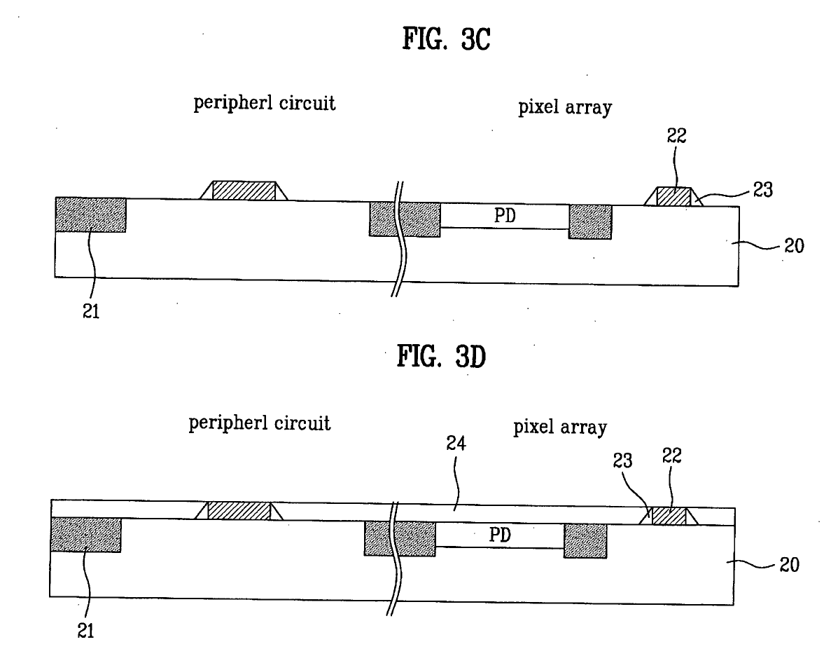

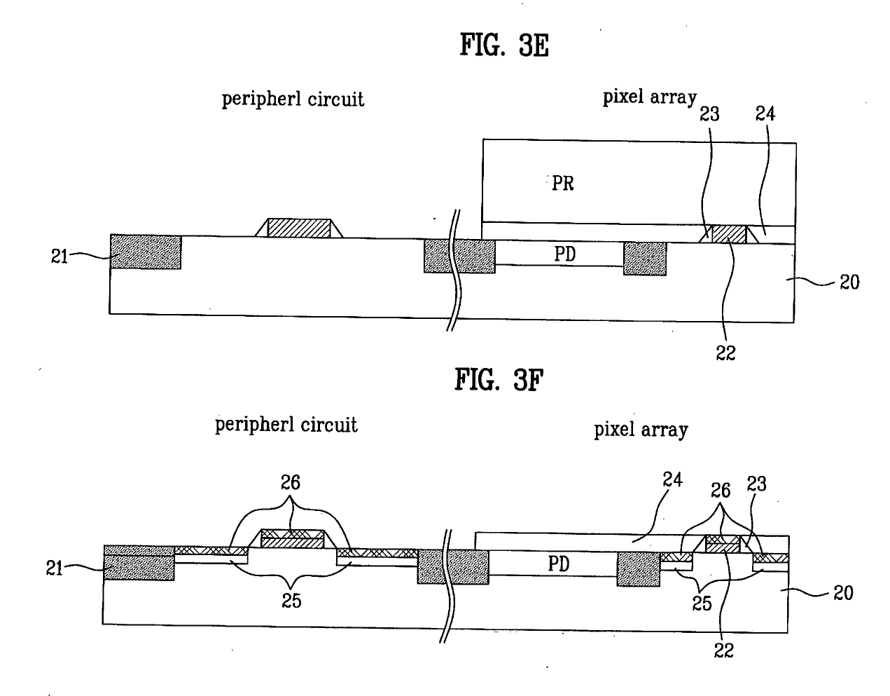

FIG. 3A to FIG. 3F are cross sectional views of the process for fabricating a CMOS image sensor according to the present invention, wherein the left side shows a peripheral circuit and the right side shows a pixel array.

As shown in FIG. 3A, a silicon semiconductor substrate 20 is defined as an active area and a field area, wherein the silicon semiconductor substrate 20 includes the peripheral circuit and the pixel array. Then, a trench is formed in the semiconductor substrate 20 of the field area. After that, a field oxide layer 21 of an STI (Shallow Trench Isolation) structure is formed by filling the trench with an insulating layer. Accordingly, the semiconductor substrate 20 is divided into the active area and the field area.

Referring to FIG. 3B, a gate insulating layer and a conductive layer of polysilicon are sequentially deposited on an entire surface of the semiconductor substrate 20, and is then selectively removed by an etching process of using a mask for patterning gate electrodes. As a result, a gate insulating layer 29 and gate electrodes 22 are formed in the peripheral circuit and the readout circuit of the pixel array.

As shown in FIG. 3C, impurity ions are implanted to the semiconductor substrate 20 with a mask, thereby forming a photodiode PD. In this case, the mask is provided to define the photodiode PD in the semiconductor substrate 20 of the pixel array. In case the semiconductor substrate 10 has the p-type, n-type impurity ions are implanted to the p-type semiconductor substrate so as to form the photodiode PD.

Next, a silicon nitride layer SiN is formed on the entire surface of the semiconductor substrate 20, and is then etch-backed to form insulating spacers 23 at both sides of the gate electrode 22. Then, impurity ions are implanted to the active area including the peripheral circuit and the readout circuit in state of using the gate electrode 22 and the insulating spacers 23 as a mask, thereby forming source and drain junctions 25.

As shown in FIG. 3D, a salicide prevention layer 24 of oxide type is formed on the entire surface of the semiconductor substrate 20. Then, a chemical mechanical polishing process is performed to the salicide prevention layer 24, whereby the salicide prevention layer 24 is planarized. At this time, as shown in the drawings, the upper surface of the gate electrode 22 is exposed in the process for planarizing the salicide prevention layer 24. However, although not shown, the upper surface of the gate electrode 22 may not be exposed.

If the upper surface of the gate electrode 22 is exposed in the process for planarizing the salicide prevention layer 24, the salicide layer is formed in the surface of the gate electrode 22 of the readout circuit during the following salicide process. As a result, it is possible to lower the resistance of the gate electrode 22.

As shown in FIG. 3E, a photoresist PR is coated on the salicide prevention layer 24, and is then patterned to remain on the pixel array by exposure and development. Then, the salicide prevention layer 24 of the peripheral circuit is etched by using the patterned photoresist PR as a mask. In this case, the field oxide layer 21 and the salicide prevention layer 24 are formed of the oxide type material. However, the salicide prevention layer 24 of the pixel array is not etched, so that the field oxide layer of the pixel array is not damaged during the aforementioned process for etching the salicide prevention layer 24.

As shown in FIG. 3F, after removing the photoresist PR, the salicide process is performed in state of using the salicide prevention layer 24 as a mask. Accordingly, salicide layers 26 are formed in the surface of the gate electrode 22 and the source and drain junctions. That is, a refractory metal layer (Co, W, etc.) is formed on the entire surface of the semiconductor substrate 20 including the salicide prevention layer 24, and then a thermal process is performed to the refractory metal layer. As a result, the deposited refractory metal layer reacts on the silicon of the lower layer, whereby the salicide layer 26 is formed in the interface between the refractory metal layer and the silicon layer. The semiconductor substrate and the gate electrode are formed of the silicon material. In this respect, the salicide layer 26 is formed on the source and drain junctions 25 and the gate electrode in the peripheral circuit, and the gate electrode 22 of the readout circuit. However, the photodiode PD and the source and drain junctions 25 of the readout circuit are masked with the salicide prevention layer 24, whereby the salicide layer 26 is not formed on the photodiode PD and the source and drain junctions 25 of the readout circuit.

In the meantime, when planarizing the salicide prevention layer 24, if the surface of the gate electrode 22 is not exposed, the pixel array is masked with the salicide prevention layer 24. Accordingly, the salicide layers 26 are formed in the surface of the gate electrode 22 and the source and drain junctions 25 of the peripheral circuit. Then, the non-reactive metal layer is selectively removed, thereby completing the CMOS image sensor according to the present invention.

As mentioned above, the method for fabricating the CMOS image sensor according to the present invention has the following advantages.

In the method for fabricating the CMOS image sensor according to the present invention, the salicide prevention layer of the pixel array is not etched. Accordingly, it is possible to prevent the field oxide layer of the pixel array from being damaged when etching the salicide prevention layer. As a result, it is possible to prevent the active area from being exposed, and to prevent the leakage current in the salicide process, thereby improving the yield in fabrication of the CMOS image sensor.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a CMOS image sensor comprising:
preparing a semiconductor substrate including a peripheral circuit and a pixel array, wherein the pixel array is comprised of a photodiode and a readout circuit;
defining an active area and a field area in the semiconductor substrate;
forming a field oxide layer in the field area of the semiconductor substrate;
forming gate electrodes in the peripheral circuit and the readout circuit of the pixel array;
forming a photodiode in a photodiode portion of the pixel array;
forming source and drain junctions at both sides of the gate electrode in the semiconductor substrate of the active area;
forming a salicide prevention layer in the semiconductor substrate of the pixel array; and
forming salicide layers in the surface of the gate electrode and the source and drain junctions in the peripheral circuit by using the salicide prevention layer as a mask.

2. The method of claim 1, wherein the process for forming the salicide prevention layer includes the step of planarizing the salicide prevention layer to expose the upper surface of the gate electrode.

3. The method of claim 2, wherein the step of planarizing the salicide prevention layer is performed by CMP (Chemical Mechanical Polishing).

4. The method of claim 1, wherein the process for forming the salicide prevention layer includes the step of planarizing the salicide prevention layer not to expose the upper surface of the gate electrode.

5. The method of claim 1, wherein the process for forming the salicide layers corresponds to the process of forming the salicide prevention layer in the surface of the gate electrode and the source and drain junctions in the peripheral circuit.

6. The method of claim 1, wherein the process for forming the salicide layers corresponds to the process of forming the salicide layers in the surface of the gate electrode of the pixel array, in the surface of the gate electrode of the peripheral circuit, and in the surface of the source and drain junctions of the peripheral circuit.
